(19) United States
(12) Patent Application Publication
(10) Pub. No.: US 2016/0378375 A1
(43) Pub. Date: Dec. 29, 2016

(54) MEMORY SYSTEM AND METHOD OF OPERATING THE SAME

(71) Applicant: SK hynix Inc., Gyeonggi-do (KR)

(72) Inventors: Young Dong Roh, Gyeonggi-do (KR); Hyun Jung Chu, Gyeonggi-do (KR)

(21) Appl. No.: 14/980,195

(22) Filed: Dec. 28, 2015

(30) Foreign Application Priority Data
Jun. 26, 2015 (KR) 10-2015-0090928

(51) Int. Cl. G06F 3/06; G11C 29/52; G06F 11/10

(52) U.S. Cl. CPC G06F 3/0619; G06F 3/0659; G06F 3/0688; G06F 11/1072; G11C 29/52; G06F 3/065

(57) ABSTRACT

A memory system includes a semiconductor memory device including a plurality of ways suitable for storing normal data and reading stored data, and a system way suitable for storing system data, and a controller suitable for controlling the semiconductor memory device to perform overall operations of the plurality of ways and an update operation of the system data of the system way.

### CROSS-REFERENCE TO RELATED APPLICATIONS

The present application claims priority to Korean patent application number 10-2015-0090928, filed on Jun. 26, 2015, the entire disclosure of which is herein incorporated by reference in its entirety.

### BACKGROUND

1. Field

Aspect of the present disclosure relate to an electronic device, and more particularly, to a memory system and a method of operating the same.

2. Description of the Related Art

A semiconductor memory device is a memory device implemented using a semiconductor such as silicon (Si), germanium (Ge), gallium arsenide (GaAs), indium phosphide (InP), and the like. The semiconductor memory device is generally classified into a volatile memory device and a nonvolatile memory device.

The volatile memory is a memory device which loses stored data when a power supply is cut off. Examples of the volatile memory include a static random access memory (SRAM), a dynamic RAM (DRAM), a synchronous DRAM (SDRAM), and the like. The nonvolatile memory is a memory device which retains stored data even when a power supply is cut off. Examples of the nonvolatile memory include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. Flash memory is generally classified into a NOR type flash memory and a NAND type flash memory.

### SUMMARY

Embodiments provide a memory system having an improved operation speed and a method of operating the same.

According to an aspect of the present disclosure, there is provided a memory system including a semiconductor memory device including a plurality of ways suitable for storing normal data and reading stored data, and a system way suitable for storing system data; and a controller suitable for controlling the semiconductor memory device to perform overall operations of the plurality of ways and an update operation of the system data of the system way.

According to an aspect of the present disclosure, there is provided a method of operating a memory system, the method including generating internal commands for controlling a semiconductor memory device and a map command for updating system data, which are stored in the semiconductor memory device, according to a command input from a host; generating a command queue by aligning the internal commands and the map command; and performing overall operations of a plurality of ways included in the semiconductor memory device and an update operation of the system data of a system way included in the semiconductor memory device according to the command queue.

According to an aspect of the present disclosure, there is provided a method of operating a memory system, the method including generating main commands for controlling a semiconductor memory device and a map command for updating system data, which are stored in the semiconductor memory device, according to a command input from a host; generating a main command queue suitable for queuing the main commands and a map command queue suitable for queuing the map command; performing overall operations of a plurality of ways included in the semiconductor memory device according to the main command queue; and performing the update operation of the system data according to the map command queue based on information of the main command queue.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a memory system according to an embodiment of the present disclosure.

FIG. 2 is a block diagram illustrating an embodiment of a semiconductor memory chip.

FIG. 3 is a flowchart illustrating an operating method of a memory system according to embodiments of the present disclosure.

FIG. 4 is a timing diagram illustrating the operating method of a memory system according to embodiments of the present disclosure.

FIG. 5 is a block diagram illustrating a common command queue according to an embodiment of the present disclosure.

FIG. 6 is a flowchart illustrating an operating method of a memory system according to embodiments of the present disclosure.

FIG. 7 is a timing diagram illustrating the operating method of a memory system according to embodiments of the present disclosure.

FIG. 8 is a block diagram illustrating a dedicated command queue according to embodiments of the present disclosure.

FIG. 9 is a diagram illustrating an exemplary implementation of a controller.

### DETAILED DESCRIPTION

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

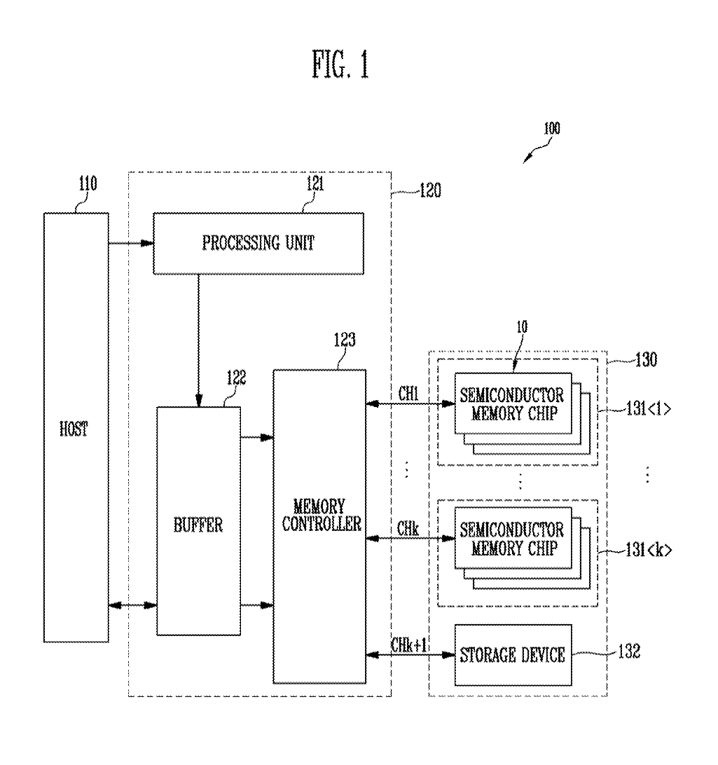

FIG. 1 is a block diagram illustrating a memory system 100 according to an embodiment of the present disclosure.

Referring to FIG. 1, the memory system 100 includes a host 110, a controller 120, and a semiconductor memory device 130.

The host 110 transmits host commands, addresses, and data to the controller 120.

The controller 120 includes a processing unit 121, a buffer 122, and a memory controller 123.

The processing unit 121 converts a logical block address provided from the host 110 into a physical block address according to map table data included in system data stored in the semiconductor memory device 130, and provides the converted physical block address to the buffer 122. The system data may include the map table data, information data related to various operational environments and status of the semiconductor memory device and history and log information data occurring during general operations thereof. The above-described system data including the map table data is stored in a storage device 132 of the semiconductor memory device 130. The system data stored in the storage device 132 are updated to new system data through an update operation of the map table data.

The buffer 122 temporarily stores a physical block address provided from the processing unit 121, and then provides the temporarily stored physical block address to the memory controller 123. Also, the buffer 122 temporarily stores data provided from the host 110, and then provides the temporarily stored data to the memory controller 123.

In response to a write request from the host 110, the memory controller 123 programs data provided from the buffer 122 into the semiconductor memory device 130 according to the physical block address provided from the buffer 122. In response to a read request from the host 110, the memory controller 123 reads programmed data in the semiconductor memory device 130 according the physical block address provided from the buffer 122, and transmits the read data to the host 110. The memory controller 123 may include internal controllers respectively corresponding to channels CH1 to CHk and CHk+1.

The semiconductor memory device 130 operates under the control of the controller 120. The semiconductor memory device 130 includes a plurality of storage areas 131<1> to 131<k> and the storage device 132. The plurality of storage areas 131<1> to 131<k> may be defined as first to kth ways, respectively. The plurality of storage areas 131<1> to 131<k> communicate with the memory controller 123 of the controller 120 through the channels CH1 to CHk respectively corresponding thereto. Each storage area 131<1> to 131<k> includes a plurality of semiconductor memory chips 10. The plurality of semiconductor memory chips 10 included in each storage area 131<1> to 131<k> may program data in a single level cell (SLC) mode, a multi level cell (MLC) mode, or a triple level cell (TLC) mode.

The storage device 132 communicates with the memory controller 123 through the channel CHk+1. The storage device 132 may be configured as a semiconductor memory chip, and stores and updates the system data including the map table data. For example, the storage device 132 may be configured as a nonvolatile memory, and configured as EEPROM, FeRAM, PCRAM, ReRAM, etc. The storage device 132 may be defined as a system way. The storage device 132 may program data in the SLC mode so as to ensure the reliability of and the system data including the map table data. The storage device 132 may store normal data as well as the map table data and the system data so as to ensure the storage capacity of the memory system 100, and the normal data may be programmed in the MLC or TLC mode. However, the present disclosure is not limited thereto, and a program operation may be performed by selecting one or more modes among a plurality of program modes.

FIG. 2 is a block diagram illustrating an embodiment of the semiconductor memory chip 10 described with reference to FIG. 1.

Referring to FIG. 2, the semiconductor memory chip 10 includes a memory cell 12 and a peripheral circuit 14. The memory cell array 12 includes a plurality of memory blocks BLK1 to BLKn. An erase operation of the semiconductor memory device 10 is performed in units of memory blocks. Program and read operations of the semiconductor memory device 10 are performed in units of pages.

The peripheral circuit 14 operates under the control of the controller 120 described with reference to FIG. 1.

During the program operation, the peripheral circuit 14 receives a program command indicating the program operation, a physical block address, and write data. One memory block and one page included therein may be selected by the physical block address. The peripheral circuit 14 may program the write data in the selected page.

During the read operation, the peripheral circuit 14 receives a read command indicating the read operation and a physical block address from the controller 120. One memory block and one page included therein may be selected by the physical block address. The peripheral circuit 14 may read data from the selected page and output the read data to the controller 120.

During the erase operation, the peripheral circuit 14 receives an erase command indicating the erase operation and a physical block address from the controller 120. One memory block may be selected by the physical block address. The peripheral circuit 14 may erase data of a memory block corresponding to the physical block address.

The semiconductor memory chip 10 is a nonvolatile memory device. As an embodiment, the semiconductor memory chip 10 may be a flash memory device.

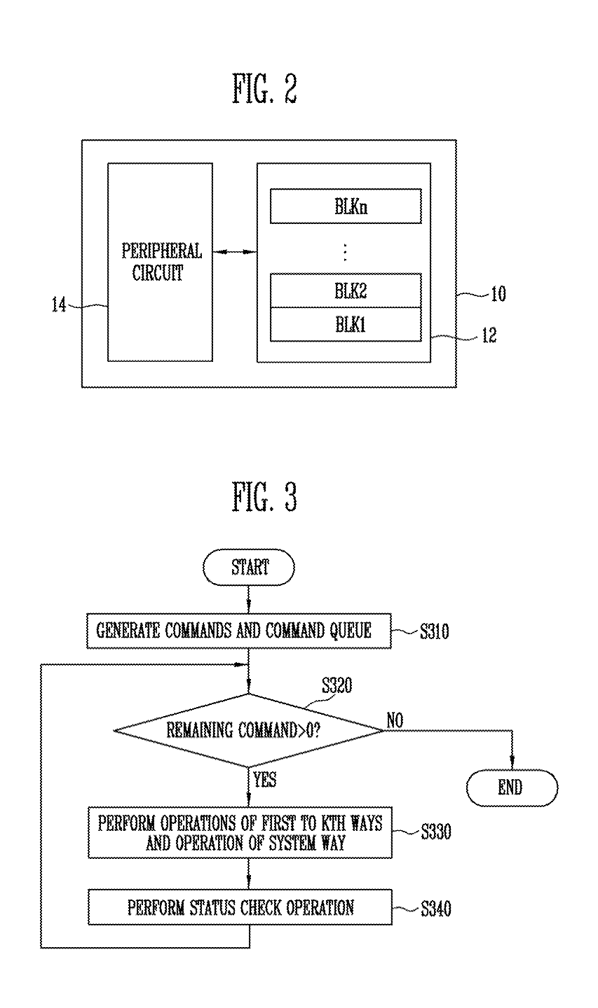

FIG. 3 is a flowchart illustrating an operating method of the memory system 100 according to an embodiment of the present disclosure.

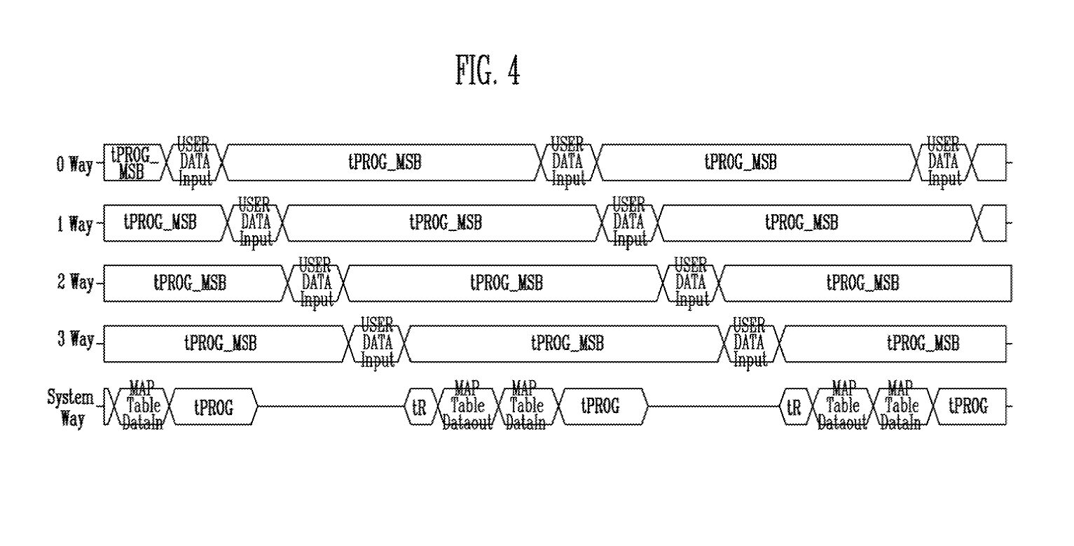

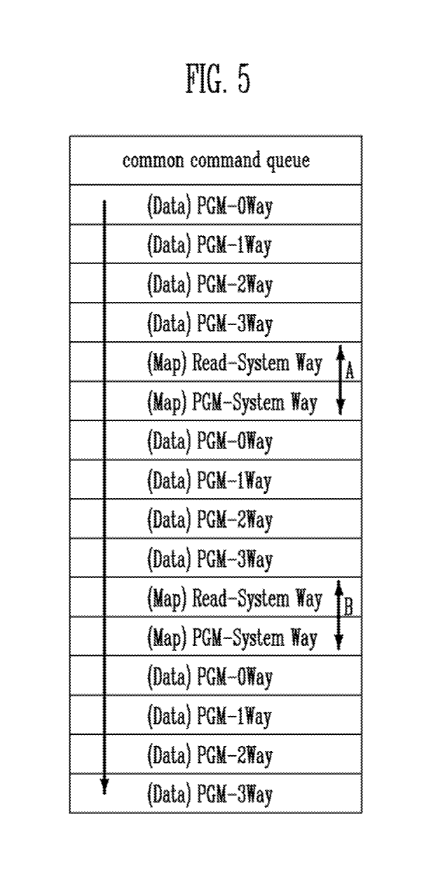

FIG. 4 is a timing diagram illustrating the operating method of the memory system 100 according to the embodiment of the present disclosure.

FIG. 5 is a block diagram illustrating a common command queue according to the embodiment of the present disclosure.

A program operation method of the memory system 100 according to an embodiment of the present disclosure will be described as follows with reference to FIGS. 1 to 5.

An example case where the program command for performing the program operation of the semiconductor memory device 130, and the update command for performing the update operation of the system data are queued in a common command queue will be described as follows.

In the present disclosure, the update operation of updating the map table data in the system way 132 will be described as an example, and the update operation of updating the system data may also be performed in a similar manner to the update operation of updating the map table data in the system way 132.

Generation of Commands and Command Queue (Step S310)

When commands, logical addresses, and data are input from the host 110, the processing unit 121 of the controller 120 generates internal commands according to the commands and sequentially aligns the generated internal commands. In this case, the internal commands include commands for performing overall operations of the first to kth ways 131<1> to 131<k> and commands for performing the update operation of updating the system data stored in the system way 132.

Referring to FIG. 5, a program command of the first way 131<1> (shown as “(Data) PGM-0way” in FIG. 5), a program command of the second way 131<2> (shown as “(Data) PGM-1way” in FIG. 5), a program command of the third way 131<3> (shown as “(Data) PGM-2way” in FIG. 5), and a program command of the fourth way 131<4> (shown as “(Data) PGM-3way” in FIG. 5) are sequentially aligned in the common command queue to perform the program operation of data. Also, update commands of the system way 132 for updating the map data and the system data (shown as “(Map) Read-System Way” and “(Map) PGM-System Way” in FIG. 5) are aligned in a subsequent section A of the common command queue. Subsequent to the section A, the program command of the first way 131<1> (shown as “(Data) PGM-0way” in FIG. 5), the program command of the second way 131<2> (shown as “(Data) PGM-1way” in FIG. 5), the program command of the third way 131<3> (shown as “(Data) PGM-2way” in FIG. 5), and the program command of the fourth way 131<4> (shown as “(Data) PGM-3way” in FIG. 5) are sequentially aligned in the common command queue to perform the program operation of data, and the update commands of the system way 132 for updating the map data and the system data (shown as “(Map) Read-System Way” and “(Map) PGM-System Way” in FIG. 5) are aligned in a subsequent section B of the common command queue.

As described above, the common command queue is generated by sequentially aligning the commands for performing the overall operations of the first to kth ways 131<1> to 131<k> and the commands for performing the update operation of included in the system data stored in the system way 132.

In the embodiment of the present disclosure, it has been described as an example that the commands of the first way to the fourth way 131 are sequentially generated. However, the present disclosure is not limited thereto, and the order in which the command queue is generated may be changed in a random manner or by a request of the processing unit 121.

Confirmation of Remaining Command (Step S320)

A determination is made as to whether to perform a remaining command queued in the common command queue when one or more of remaining commands are queued in the common command queue. For example, when the number of the remaining command is greater than 0, the remaining command is performed at step S330. When the remaining command is 0, all operations are ended.

Operations of First to Kth Ways and Operation of System Way (Step S330)

As a result of the determination of step S320, when the number of the remaining commands is greater than 0, which means that one or more of the remaining commands are queued in the common command queue, an operation corresponding to the remaining command is performed. In this case, the operation corresponding to the remaining command may be performed according to an order of queue in the common command queue.

For example, as shown in FIG. 5, after the program operations of the first to fourth ways 131 are sequentially performed, the update operation of the system data in the system way 132 is performed by performing read and program operations of the system way 132.

In this case, during the program operations of the first to fourth ways, a command of a higher priority may be first performed by a request of the processing unit 121.

Referring to FIG. 4, in response to the program command queued in the common command queue described with reference to FIG. 5, the program operations and the update operation of the system data in the system way 132 are sequentially and repeatedly performed on the first way (shown as “0 Way” in FIG. 4) to the fourth way (shown as “3 Way” in FIG. 4) and the system way 132 (shown as “System Way” in FIG. 4). For example, the input operations of user data (shown as “USER DATA INPUT” in FIG. 4) and the program operations tPROG_MSB of a most significant bit (MSB) are performed on the first way to the fourth way 131.

Then, in response to the update command queued in the common command queue described with reference to FIG. 5, the read operation tR, the output operation of the map table data (shown as “MAP Table Data out” In FIG. 4), the input operation of the map table data (shown as “MAP Table Data in” in FIG. 4), and the program operation tPROG of the map table data are sequentially performed on the system way 132 (shown as “System Way” in FIG. 4).

In this case, the program operations of the first way to the fourth way 131 may be performed by selecting one or more program modes among the SLC mode, the MLC mode, and the TLC mode. On the other hand, the program operation of the system way 132 may be performed in the SLC mode so as to ensure reliability. The program operation of the system way 132 is fixed to the SLC mode during the program operation of the system data. Therefore, it is possible to skip an operation for selecting the program mode during the program operation of the system data. Thus, overheads of the processing unit 121 and the memory controller 123 are prevented.

Status Check Operation (Step S340)

Upon completion of step S330, it is determined whether the program and update operations of the first to kth ways 131 and the system way 132 are normally performed through a status check operation of the first to kth ways 131 and the system way 132. Steps S320 to S340 are repeated until no remaining command is queued in the common command queue.

In the above-described embodiment, the program operation of the memory system has been described as an example, but the same method may also be applied to the read operation of the memory system.

According to the present disclosure, the map data is stored in the storage device 132 included in the semiconductor memory device 130, and thus the program operations of the first to fourth ways 131 can be performed by selecting one or more program modes among the SLC mode, the MLC mode, and the TLC mode while the program operation of the system way 132 can be performed with the SLC mode during the update operation of the system data in the system way 132. Thus, it is possible to improve the operation speed of the memory system and prevent overheads of the processing unit 121 and the memory controller 123.

Also, the commands of the first to fourth ways 131 and the command of the system way 132 are aligned, thereby generating the common command queue. Thus, it is possible to simplify the overall operations of the first to fourth ways and the update operation of the system data in the system way 132.

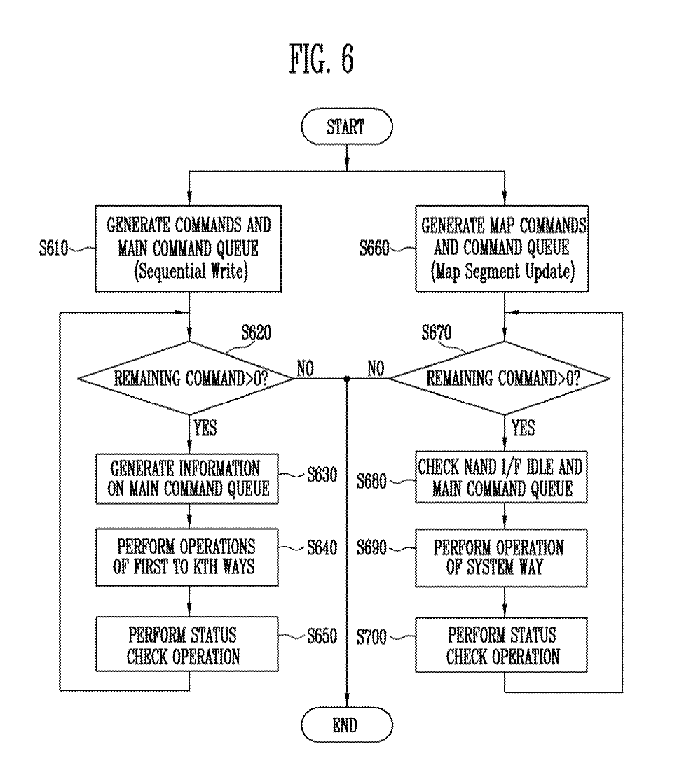

FIG. 6 is a flowchart illustrating an operating method of the memory system 100 according to an embodiment of the present disclosure.

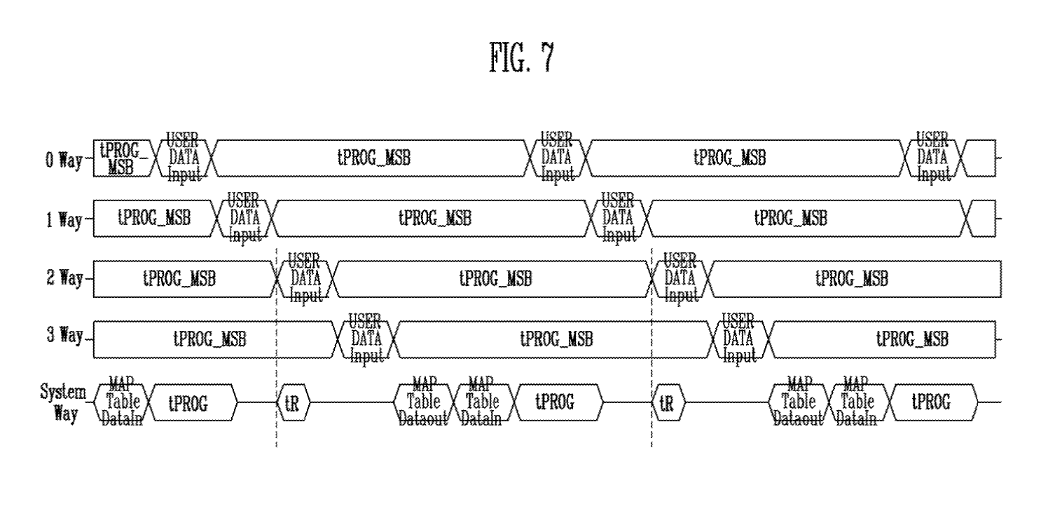

FIG. 7 is a timing diagram illustrating the operating method of the memory system 100 according to the embodiment of the present disclosure.

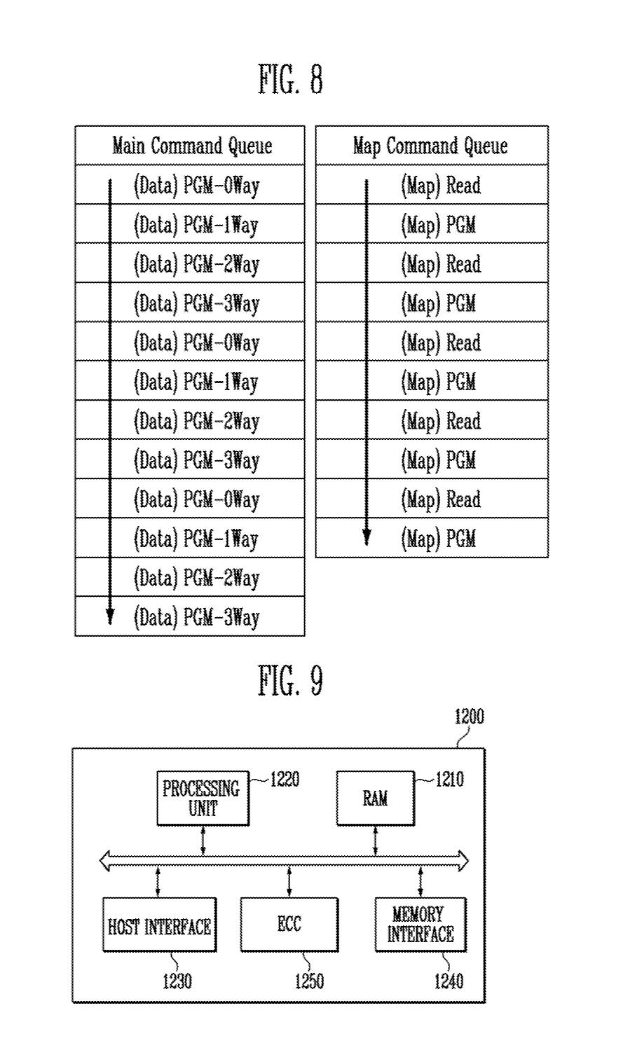

FIG. 8 is a block diagram illustrating a dedicated command queue according to the embodiment of the present disclosure.

A program operation method of the memory system 100 according to an embodiment of the present disclosure will be described as follows with reference to FIGS. 1, 2, and 6 to 8.

An example case where the program command for performing the program operation of the semiconductor memory device 130, and the update command for performing the update operation of the system data are separately queued in corresponding dedicated command queues will be described as follows.

For illustrative purposes, the update operation of updating the map table data in the system way 132 will be described as an example. The update operation of updating the system data may also be performed in a similar manner to the update operation of updating the map table data in the system way 132.

Generation of Main Commands and Command Queue (Step S610)

When commands, logical addresses, and data are input from the host 110, the processing unit 121 of the controller 120 generates internal commands according to the commands and sequentially aligns the generated internal commands. In this case, the internal commands are commands for performing overall operations of the first to kth ways 131<1> to 131<k>.

Referring to FIG. 8, a program command of the first way 131<1> (shown as “(Data) PGM-0way” in FIG. 8), a program command of the second way 131<2> (shown as “(Data) PGM-1way” in FIG. 8), a program command of the third way 131<3> (shown as “(Data) PGM-2way” in FIG. 8), and a program command of the fourth way 131<4> (shown as “(Data) PGM-3way” in FIG. 8) are sequentially aligned in the common command queue to perform the program operation of data, and these program commands are repeatedly aligned in this order, thereby generating a main command queue.

In the embodiment of the present disclosure, the commands of the first way to the fourth way 131 are sequentially generated. However, the present disclosure is not limited thereto, and the order in which the command queue is generated may be changed in a random manner or by a request of the processing unit 121.

Confirmation of Remaining Command (Step S620)

It is determined whether to perform a remaining command of the first way to the fourth way 131 queued in the main command queue when one or more of remaining commands of the first way to the fourth way 131 are queued in the main command queue. For example, when the number of the remaining commands of the first way to the fourth way 131 is greater than 0, the remaining commands of the first way to the fourth way 131 are performed at step S630. When the remaining command is 0, all operations of the first way to the fourth way 131 are ended.

Generation of Information on Main Command Queue (Step S630)

As a result of the determination of step S620, when the number of the remaining commands of the first way to the fourth way 131 is greater than 0, which means that one or more of the remaining commands of the first way to the fourth way 131 are queued in the main command queue, information on the main command queue generated at step S610 is arbitrarily stored. The information on the main command queue represents whether each of the first way to the fourth way 131 is in an idle state or in a busy state, whether any command of the first way to the fourth way 131 remains in the main command queue, whether the subsequent command of the main command queue is for current one in the busy state among the first way to the fourth way 131, etc.

Operations of First to Kth Ways (Step S640)

An operation corresponding to the remaining command of the first way to the fourth way 131 is performed according to the main command queue. For example, as shown in FIG. 8, the program operations of the first to fourth ways 131 are sequentially performed. In this case, during the program operations of the first to fourth ways 131, a command of a higher priority may be first performed by a request of the processing unit 121.

Referring to FIG. 7, in response to the program command of the first to kth ways 131 queued in the main command queue described with reference to FIG. 8, the program operations are sequentially and repeatedly performed on the first way (shown as “0 Way” in FIG. 7) to the fourth way (shown as “3 Way” in FIG. 7). For example, the input operations of user data (shown as “USER DATA INPUT” in FIG. 7) and the program operations tPROG_MSB of a most significant bit (MSB) are performed on the first way to the fourth way 131.

In this case, the program operations of the first way to the fourth way 131 may be performed by selecting one or more program modes among the SLC mode, the MLC mode, and the TLC mode.

Status Check Operation (Step S650)

Upon completion of step S640, it is determined whether the program and update operations of the first to kth ways 131 are normally performed through a status check operation of the first to kth ways 131. The steps S620 to S650 are repeated until no remaining command of the first to kth ways 131 is queued in the main command queue.

Generation of Map Commands and Command Queue (Step S660)

When commands, logical addresses, and data are input from the host 110, the processing unit 121 of the controller 120 generates internal commands according to the commands, and sequentially aligns the generated internal commands. In this case, the internal commands are commands for the update operation of updating the system data in the system way 132.

Step S660 for a map command queue of the system way 132 may be performed in parallel to step S610 for the main command queue of the first to kth ways 131. Steps S660 and S610 may be simultaneously performed.

Referring to FIG. 8, update commands of the system way 132 for updating the map data and the system data (shown as “(Map) Read” and “(Map) PGM” in FIG. 8) are repeatedly aligned in the map command queue, thereby generating the map command queue.

Confirmation of Remaining Command (Step S670)

It is determined whether to perform a remaining command queued in the map command queue when one or more of remaining commands of the system way 132 are queued in the map command queue. For example, when the number of the remaining commands of the system way 132 is greater than 0, the remaining commands of the system way 132 are performed at step S680. When the remaining command of the system way 132 is 0, all operations of the system way 132 are ended

Check of NAND I/F Idle and Main Command Queue (Step S680)

As a result of the determination of step S670, when the number of the remaining commands of the system way 132 is greater than 0, which means that one or more of the remaining commands of the system way 132 are queued in the map command queue, it is determined whether to perform the update operation of the system data in the system way 132 by analyzing the information on the main command queue generated at step S630. For example, when the main command queue satisfies at least one of the following conditions, it is determined to perform the update operation of the system data in the system way 132:

(i) Perform a map command operation when NAND I/F is in the idle state.

(ii) The first to kth ways 131 are in the busy state.

(III) The number of the remaining commands of the first to kth ways 131 included in the main command queue is 0.

(iv) The subsequent command of the main command queue is for current one in the busy state among the first way to the fourth way 131.

Operation of System Way (Step S690)

As a result of the determination of step S680, it is determined to perform the update operation of the system data in the system way 132, and the update operation of the system data in the system way 132 is performed on the system way 132.

Referring to FIG. 7, in response to the update command queued in the map command queue described with reference to FIG. 8, the read operation tR, the output operation of the map table data (shown as “MAP Table Data out” in FIG. 7), the input operation of the map table data (shown as “MAP Table Data in” in FIG. 7), and the program operation tPROG of the map table data are sequentially performed on the system way 132 (shown as “System Way” in FIG. 7).

As shown in FIG. 7, the update operation of the system data in the system way 132 may be simultaneously performed with the program operations of the first to fourth ways 131.

In this case, the program operation of the system way 132 may be performed in the SLC mode so as to ensure reliability. The program operation of the system way 132 is fixed to the SLC mode during the program operation of the system data, and hence it is possible to skip an operation for selecting the program mode during the program operation of the system data. Thus, overheads of the processing unit 121 and the memory controller 123 are prevented.

Status Check Operation (Step S700)

Upon completion of step S690, it is determined whether the update operation of the system way 132 is normally performed through a status check operation of the system way 132. The steps S670 to S700 are repeated until no remaining command of the system way 132 is queued in the map command queue.

In the above-described embodiment, the program operation of the memory system has been described as an example, but the same method may also be applied to the read operation of the memory system.

As described above, according to the present disclosure, the map data is stored in the storage device 132 included in the semiconductor memory device 130, and thus the program operations of the first to fourth ways 131 can be performed by selecting one or more program modes among the SLC mode, the MLC mode, and the TLC mode while the program operation of the system way 132 can be performed with the SLC mode during the update operation of the system data in the system way 132. Thus, it is possible to improve the operation speed of the memory system and prevent overheads of the processing unit 121 and the memory controller 123.

FIG. 9 is a diagram illustrating an implementation of the controller 120 described with reference to FIGS. 1 to 8.

Referring to FIG. 9, the controller 1200 includes a RAM 1210, a processing unit 1220, a host interface 1230, a memory interface 1240, and an error correction block (ECC) 1250.

The processing unit 1220 controls overall operations of the controller 1200. The RAM 1210 may be used as at least one of an operation memory of the processing unit 1220, a cache memory between the semiconductor memory device 130 (see FIG. 1) and the host, and a buffer memory between the semiconductor memory device 130 and the host. The processing unit 1220 and the RAM 1210 may perform functions of the processing unit 121, the buffer 122, and the memory controller 123 of FIG. 1. For example, the processing unit 1220 may load program commands, data files, data structures, and the like from the RAM 1210, and execute the loaded data, thereby performing the functions of the processing unit 121, the buffer 122, and the memory controller 123.

Additionally, the RAM 1210 may be used as the buffer 122 of FIG. 1.

The host interface 1230 includes a protocol for exchanging data between the host and the controller 1200. As an example, the controller 1200 is configured to communicate with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1240 interfaces with the semiconductor memory device 130. For example, the memory interface 1240 may include a NAND interface or a NOR interface. The memory interface 1240 includes an additional channel for interfacing with a map segment storage device of the semiconductor memory device 130.

The controller 1200 and the semiconductor memory device 130 may be integrated into one semiconductor device. As an example, the controller 1200 and the semiconductor memory device 130 may be integrated into one semiconductor device to constitute a memory card. For example, the controller 1200 and the semiconductor memory device 130 may be integrated into one semiconductor device, to constitute a memory card such as a PC card (personal computer memory card international association (PCMCIA)), a compact flash (CF) card, a smart media card (SM or SMC), a memory stick, a multimedia card (MMC, RS-MMC or MMCmicro), an SD card (SD, miniSD, microSD or SDHC), or a universal flash storage (UFS).

The controller 1200 and the semiconductor memory device 130 may be integrated into one semiconductor device to constitute a semiconductor drive (solid state drive (SSD)). When the controller 1200 and the semiconductor memory device 130 are used as the SDD, the operating speed of the host can be remarkably improved.

As another example, the controller 1200 and the semiconductor memory device 130 may be provided as one of various components of an electronic device such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

As an embodiment, the controller 1200 and the semiconductor memory device 130 may be packaged in various forms. For example, the controller 1200 and the semiconductor memory device 130 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi chip package (MCP), wafer-level fabricated package (WFP), or wafer-level processed stack package (WSP).

According to the present disclosure, it is possible to provide a memory system having an improved operation speed and a method of operating the same. Further, it is possible to reduce the overhead and complexity of a flesh conversion layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory system comprising:
a semiconductor memory device including a plurality of ways suitable for storing normal data and reading stored data, and a system way suitable for storing system data; and
a controller suitable for controlling the semiconductor memory device to perform overall operations of the plurality of ways and an update operation of the system data of the system way.

2. The memory system of claim 1, wherein the system way stores the normal data so as to ensure the capacity of the memory system.

3. The memory system of claim 1, wherein the controller controls the semiconductor memory device to perform a program or read operation by selecting one of a plurality of program modes during the update operation of the system data of the system way.

4. The memory system of claim 1, wherein the controller includes:
a processing unit suitable for receiving a logical address from a host, and converting the received logical address into a physical address; and
a memory controller suitable for controlling the semiconductor memory device to receive data from the host, and storing the received data in the plurality of ways of the semiconductor memory device according to the physical address.

5. The memory system of claim 4, wherein, in response to a command from the host, the processing unit generates a command queue by aligning main commands of the plurality of ways and a map command of the system way.

6. The memory system of claim 5,
wherein the memory controller controls the semiconductor memory device to sequentially perform a plurality of commands according to the command queue,
wherein the memory controller controls the semiconductor memory device to first perform a command of a higher priority among the plurality of commands despite of the command queue.

7. The memory system of claim 5, wherein the command queue includes a main command queue suitable for queuing the main commands, and a map command queue suitable for queuing the map command.

8. The memory system of claim 5, wherein the memory controller controls the semiconductor memory device to perform the overall operations of the plurality of ways and the update operation of the system data of the system way according to the command queue.

9. The memory system of claim 7,
wherein the memory controller controls the semiconductor memory device to perform the overall operations of the plurality of ways according to the main command queue, and to perform the update operation of the system data of the system way according to the map command queue, and
wherein the overall operations of the plurality of ways and the update operation of the system data of the system way are performed in parallel to each other.

10. The memory system of claim 1, wherein the memory controller controls the semiconductor memory device to perform the overall operations of the plurality of ways in one of a single level cell (SLC) mode, a multi level cell (MLC) mode, and a triple level cell (TLC) mode, and to perform the update operation of the system data of the system way in the SLC mode.

11. The memory system of claim 9, wherein, when NAND I/F is in an idle state, the plurality of ways are in a busy state, a number of remaining commands in the main command queue is 0, or a subsequent command of the main command queue is for current one in a busy state among the plurality of ways, the controller controls the semiconductor memory device to perform the update operation of the system data.

12. The memory system of claim 1, wherein the system data include map data.

13. A method of operating a memory system, the method comprising:
generating internal commands for controlling a semiconductor memory device and a map command for updating system data, which are stored in the semiconductor memory device, according to a command input from a host;
generating a command queue by aligning the internal commands and the map command; and
performing overall operations of a plurality of ways included in the semiconductor memory device and an update operation of the system data of a system way included in the semiconductor memory device according to the command queue.

14. The method of claim 13, further comprising:
after the overall operations and the update operation of the system data are performed, performing a status check operation on the plurality of ways and the system way and then confirming whether any command remains in the command queue; and
repeating the method according to the remaining command until no command remains in the command queue.

15. The method of claim 13,
wherein the performing of the overall operations is performed in one of a single level cell (SLC) mode, a multi level cell (MLC) mode, or a triple level cell (TLC) mode, and
wherein the performing of the update operation is performed in the SLC mode.

16. The method of claim 13, wherein the system data include map data.

17. A method of operating a memory system, the method comprising:
generating main commands for controlling a semiconductor memory device and a map command for updating system data, which are stored in the semiconductor memory device, according to a command input from a host;
generating a main command queue suitable for queuing the main commands and a map command queue suitable for queuing the map command;
performing overall operations of a plurality of ways included in the semiconductor memory device according to the main command queue; and
performing the update operation of the system data according to the map command queue based on information of the main command queue.

18. The method of claim 17, wherein, when NAND I/F is in an idle state, the plurality of ways are in a busy state, a number of remaining commands in the main command queue is 0, or a subsequent command of the main command queue is for current one in a busy state among the plurality of ways, the update operation of the system data is performed.

19. The method of claim 17, wherein the overall operations and the update operation are performed in parallel to each other.

20. The method of claim 17,
wherein the overall operations are performed in one of a single level cell (SLC) mode, a multi level cell (MLC) mode, and a triple level cell (TLC) mode, and
wherein the update operation is performed in the SLC mode.
